(19) United States
(12) Patent Application Publication
(10) Pub. No.: US 2009/0289666 A1
(43) Pub. Date: Nov. 26, 2009

(54) Direct digital synthesis frequency synthesizer and associated methods

(76) Inventor: John Kump, Hillsborough, CA (US)

Correspondence Address: Goodwin Procter LLP;Attn: Patent Administrator, 135 Commonwealth Drive, Menlo Park, CA, 94025-1105, US

(21) Appl. No.: 12/125,190

(22) Filed: May 22, 2008

(51) Int. Cl. H03C 3/00; H03L 7/00

(52) U.S. Cl. 327/101; 327/141

(57) ABSTRACT

An acousto-optic system is provided that has an acousto-optic device coupled to a DDS IC controller. The DDS controller provides amplitude modulation to adjust output power synchronously with changes in frequency when activating a different frequency.

### FIELD OF THE INVENTION

This invention relates generally to acousto-optic systems, and more particularly to acousto-optic systems where an acousto-optic device and a DDS controller form an integrated solution.

### DESCRIPTION OF THE RELATED ART

Acoustooptic systems can be complex and require time consuming setup to establish optimal performance. Tolerances in the fabrication of the acoustooptic device and its mounting hardware can make each setup a unique alignment. The mechanical alignment of the AO device's acoustic wave to the incident optical beam is one challenge; the electrical alignment of the RF drive is another.

Acoustooptic systems cover a wide range of applications including scanning, filtering, modulating, and adaptive optics. Adaptive optics is general field including traveling lens devices, chip lens devices, and other dynamically configurable optical elements. A relatively new adaptive optics applications is in high performance pulsed laser communication systems. “Aberrations disturbing the wavefront of a laser communications link lead to reduced power which directly increases the communication bit error rate. Correction of these wavefront aberrations is essential to efficient communications with optics. A method of correcting wavefront aberrations with” an acoustooptic device requires forming precise ultrasonic waveforms inside them. The optical response resulting from these waveforms creates a shapeable phase profile of an emergent optical wavefront. The RF waveform supplied to the acoustooptic device's transducer plays a critical role in this. Therefore it is the intent here to look at the requirements of ultrasonic waveform creation and its impact on RF waveform generation. Jeffery A. Butterworth, et al. “Wavefront Aberration Correction Using Zernike Polynomials Parameterization of Optical Phased Arrays” Conference Paper Reprint, Proceedings of the AIAA Guidance, 20-23 Aug. 2007, Myrtle Beach, S.C.

A scanning acoustooptic system provides a good illustration into the challenges facing the system designer for precise ultrasonic waveform creation inside an acoustooptic deflector, AOD. The amplitude response of the AOD is the diffracted light intensity versus scan frequency, or in other words, the scan intensity profile. A well designed system delivers a defined scan intensity profile, uniformly and repeatedly. Once the mechanical alignment has been achieved, the electrical alignment of the RF drive becomes the dominant factor in achieving a scan intensity profile. An acoustooptic deflector inherently incurs Bragg mismatch errors as it responds from one frequency to the next. Bragg mismatch errors reduce diffracted light intensity. The larger the frequency-span of operation the more change in diffracted light intensity. The Bragg-bandwidth of an acoustooptic deflector is a primary concern for system performance; the scan intensity profile is a direct descendant. Enhance Bragg-bandwidth deflectors can be realized utilizing phased array transducers. They produce active acoustic beam steering to combat Bragg mismatch errors and are themselves very sophisticated devices requiring special attention to the electrical alignment of the RF drive. The RF phase management of each transducer from the electronics can be a challenge all on its own. Propagation delays from one system's electrical interconnect to the next is just one of the areas where phase errors crop up. For more information on phased array acoustooptic deflectors the curious reader can find further discussion in the accompanying reference. Douglas A. Pinnow, “Acousto-Optic Light Deflection: Design Considerations for First Order Beam Steering Transducers” IEEE Transactions on Sonics and Ultrasonics, Vol. SU-18, NO. 4, October 1971.

The convolution of error generating elements such as Bragg mismatch, differential RF phase mismatch, impedance mismatch, the electronic driver's amplitude and frequency response, to name a few, affect the requirements for ultrasonic wave creation inside the AOD. Its optical response is a product of these elements and the incident optical wave. If the scope of the acoustooptic system is to tailor the AOD's optical response to a desired function, then the scope quickly develops into a real problem requiring sophisticated compensation schemes and resources to achieve them.

In the past, when system designers developed compensation schemes, they had to decide what complex circuits are necessary for insuring the AOD's output response. The required RF waveform being issued to the AOD is a spectrum of instantaneous frequency-amplitude-phase relationships synchronized to an activity of the work piece. The frequency-amplitude-phase relationship is a synchronized event too. The frequency generator, modulation controller, and vector modulator need individual instructions synchronized for an event. In high-speed applications where the time duration of the waveform is on the order of a micro-second or less, one needs to pay close attention to circuit topology to achieve such synchronization. This task, the design of complex circuits to achieve an AOD's optical response, is what is at stake. It takes time and money to figure out and places the burden on the user. To date nothing on the market addresses this or provides a solution eliminating this burden. This invention takes a novel approach to solving this complex and time consuming problem by considering the AOD with its driver an integrated subsystem and tackles this burden.

### SUMMARY OF THE INVENTION

An object of the present invention is to provide an improved acousto-optic system.

Another object of the present invention is to provide an acousto-optic system where an acousto-optic device and a DDS controller form an integrated solution.

A further object of the present invention is to provide an acousto-optic system with smart recognition, feedback, and host command and control that enables a user to extract maximum performance out of acousto-optic system.

Another object of the present invention is to provide an acousto-optic system with external amplitude control to adjust output power of the system synchronously with changes in frequency when activating a different frequency profile.

Yet another object of the present invention is to provide an acousto-optic system with random modulation of frequency, amplitude and/or phase for a modulation controller.

Still another object of the present invention is to provide an acousto-optic system with external amplitude control to adjust output power synchronously with changes in RF frequency of a DDS IC when activating different profile pins of the DDS IC.

A further object of the present invention is to provide an acousto-optic system with a programmable frequency spectrum, programmable amplitude spectrum and a programmable phase spectrum for an acousto-optic device.

Another object of the present invention is to provide external modulation control to adjust output, frequency, phase and/or amplitude.

These and other objects of the present invention are achieved in an acousto-optic system that includes an acousto-optic device. A direct digital synthesizer integrated circuit (DDS IC) controller is coupled to the acousto-optic device. The DDS controller provides amplitude modulation to adjust output power synchronously with changes in frequency when activating a different frequency profile.

In another embodiment of the present invention, an acousto-optic system has an acousto-optic device configured to receive an RF input and a modulation controller coupled to an RF output and to the acousto-optic device. At least a first DDS IC is coupled to the modulation controller. A logic device is coupled to the first DDS IC. Circuitry is coupled to or is incorporated into the logic device. In one embodiment, the circuitry provides modulation control to adjust output frequency, phase and/or amplitude.

In another embodiment of the present invention, an acousto-optic system has an acousto-optic device configured to receive an RF input and a modulation controller coupled to an RF output and to the acousto-optic device. At least a first DDS IC is coupled to the modulation controller. A logic device is coupled to the first DDS IC. Circuitry provides external amplitude control to adjust output power synchronously with changes in RF frequency of the first DDS IC when activating different profile pins of the first DDS IC.

In another embodiment of the present invention, an acousto-optic system has an acousto-optic device configured to receive an RF input and a modulation controller coupled to an RF output and to the acousto-optic device. At least a first DDS IC is coupled to the modulation controller. A logic device is coupled to the first DDS IC. Circuitry provides a programmable frequency spectrum, programmable amplitude spectrum and a programmable phase spectrum for the acousto-optic device.

In another embodiment of the present invention, an acousto-optic system has an acousto-optic device configured to receive an RF input and a modulation controller coupled to an RF output and to the acousto-optic device. At least a first DDS IC is coupled to the modulation controller. A logic device is coupled to the first DDS IC. Circuitry provides external modulation control to adjust output frequency, phase and/or amplitude.

### BRIEF DESCRIPTION OF THE DRAWINGS

FIG. 1 is a block diagram illustrating one embodiment of the present invention with an acousto-optic device configured to receive an RF input, at least a first DDS IC, a logic device coupled to the first DDS IC and circuitry coupled to or incorporated into the logic device.

FIG. 2 is block diagram of an embodiment of the present invention with two DDS's.

FIG. 3 is block diagram illustrating a two port embodiment of the present invention.

FIG. 4 is a block diagram illustrating a four port embodiment of the present invention.

FIG. 5 illustrates one embodiment of a system of the present invention that includes a light source, target and photodetector.

### DETAILED DESCRIPTION OF THE PREFERRED EMBODIMENTS

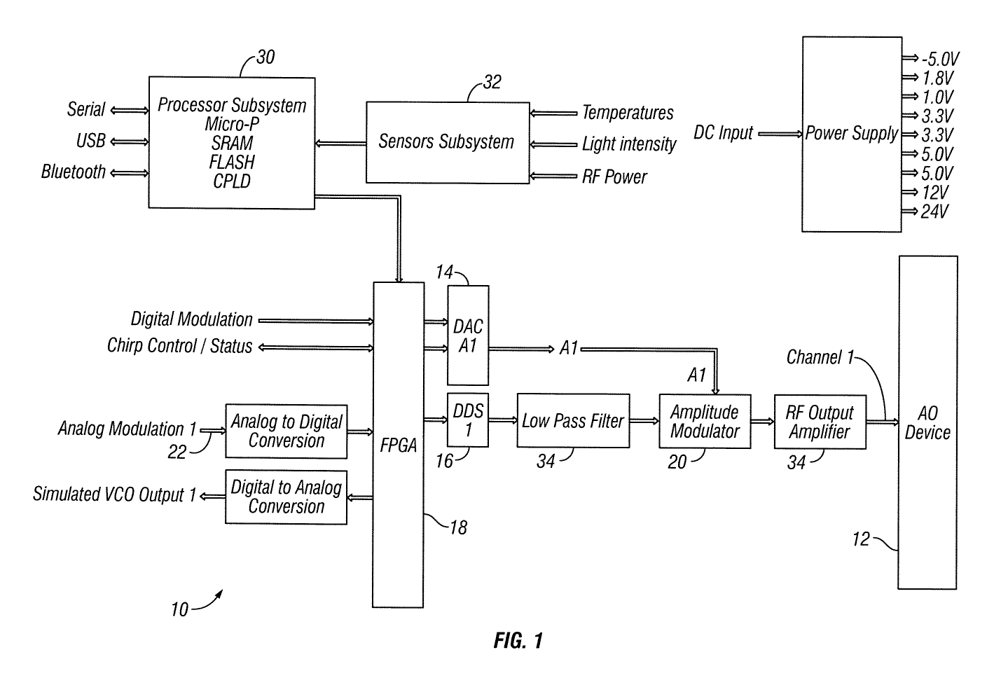

Referring to FIG. 1, in one embodiment of the present invention, an acousto-optic system, generally denoted as element 10, includes an acousto-optic device 12 coupled to a DDS controller 14. The DDS controller 14 provides amplitude modulation to adjust output power synchronously with changes in frequency when activating a different frequency profile.

Suitable acousto-optic devices 12 include but are not limited to acoustooptic deflectors, acoustooptic tunable filters, acoustooptic modulators, acoustooptic adaptive-optics, Bragg-Cells and the like.

The DDS controller 14 includes at least a first DDS IC 16 and separate circuitry 18 that tracks a user's request to switch to a frequency profile and perform an amplitude adjustment external to the DDS IC 16. In one embodiment, the DDS controller 14 includes at least a first DDS IC 16 and at least a first modulation controller 20 that can be internal or external to the circuitry 18.

The system 10 is an integrated subsystem. The acousto-optic device 12 is connected to the DDS controller. The DDS controller 14 is the central element which interfaces to the acousto-optic device 12 operation and performance through feedback from various sensors. Besides the DDS controller's RF connection to the acousto-optic device 12, a 12C bus can extend between the DDS controller 14 and the acousto-optic device 12 to enable communications. Device specific information is typically preprogrammed at the factory into the acousto-optic device 12 for smart recognition. Smart recognition embeds device identification, which includes device personality, for passing behavioral data to the DDS controller 14. Behavioral data is used by the DDS controller 14 to servo the acousto-optic device's response. Included in the acousto-optic device 12 identification are manufacturing traceability, test data, and the DDS controller configuration file (CCF). Among other things, the CCF passes the acousto-optic device 12 factory-programmed frequency-amplitude-phase relationship to achieve a uniform diffracted light intensity within the acousto-optic device 12 frequency range; a unique feature of this subsystem's ability. The DDS controller 14 is also designed to communicate to several sources for command and control. Independent host modulation control, host computer, and service access allow for freedom in a system's design architecture. All or part of these communication paths can be operational to meet any system design needs.

By way of non-limiting example, the speed to switch to the frequency profile and perform the amplitude adjustment external to the DDS IC 16 is at least, 1 millisecond, 1 microsecond, 500 nanoseconds, 100 nanoseconds, 10 nanoseconds, 4 nanoseconds and the like.

In one embodiment, a change in the output RF frequency of the DDS IC 16 is limited by a clock speed of the DDS IC 16. In another embodiment, a change in the output RF amplitude of the DDS controller 14 is limited by the bandwidth of the modulation controller 20. In yet another embodiment, a change in the output RF phase of the DDS controller 14 is limited by the bandwidth of the modulation controller 20.

Frequencies can be pre-loaded into frequency profile registers in the DDS IC 16 and frequencies are injected into the acousto-optic device 12 at optimized amplitudes.

As a non-limiting example, frequencies can be randomly accessed and injected into the acousto-optic device 12 at optimized amplitudes within, 1 clock cycle of the DDS IC 16, 2 clock cycles of the DDS IC 16, 3 clock cycles of the DDS IC 16, 4 clock cycles of the DDS IC 16, 5 clock cycles of the DDS IC 16 and the like.

As another non-limiting example, frequencies can be sequentially accessed and injected into the acousto-optic device 12 at optimized amplitudes at a switching speed of at least, 1 megahertz, 2 megahertz, 5 megahertz, 50 megahertz, 100 megahertz, 200 megahertz, 250 megahertz and the like.

In one embodiment, the DDS IC 16 operates in a direct switch mode, randomly selects pre-loaded frequencies from the DDS IC 16 and then injects frequencies. In another embodiment, the DDS IC 16 operates in a RAM mode with pre-load frequencies in the DDS IC 16. In this embodiment, the DDS IC 16 is in playback mode and generates a waveform that is at least the clock rate of the DDS IC 16.

In another embodiment, the DDS controller 14 includes at least the first DDS IC 16 and the circuitry 18 that tracks a user's request to directly frequency modulate the DDS IC 16. In this embodiment, modulation controller 20 in the DDS controller 14 can be externally modulated by a host interface 22 (user interface). In one embodiment, a second DDS IC 24, the modulation controller 20 and the host interface 22 are included. The host interface 22 sends modulation data to the modulation controller 20, and modulates amplitude and phase external to the first and second DDS IC's 16 and 24.

In another embodiment, the DDS controller 14 includes at least the first DDS IC 16 and the circuitry 18 to directly modulate amplitude or frequency of the first DDS IC 16. In this embodiment, the first DDS IC 16 and the separate circuitry 18 directly modulate amplitude and frequency of the DDS IC 16 simultaneously. In this embodiment, the host interface 22 sends modulation data to the modulation controller 20, frequency modulates the first and second DDS IC's 16 and 24 and externally phase modulates the first and second DDS IC's 16 and 24. The first DDS IC 16 and the separate circuitry 18 can simultaneously modulate frequency and phase of the DDS controller 14.

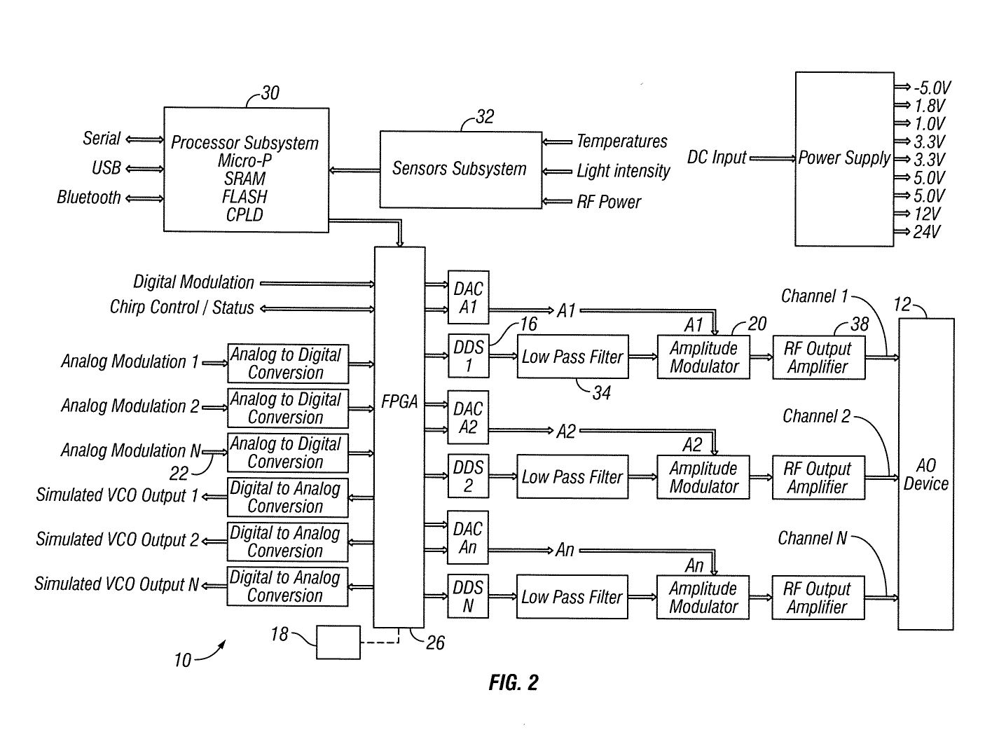

Referring now to FIG. 2, in one embodiment of the present invention, the acousto-optic system 10 has an acousto-optic device 12 configured to receive an RF input and an modulation controller 20 coupled to an RF output and to the acousto-optic device. At least the first DDS IC 16 is coupled to the modulation controller 20. A logic device 26 is coupled to the first DDS IC 16. The logic device 26 can be a, CPLD, PLD, ASIC, FPGA and the like.

Circuitry 18 is coupled to or incorporated into the logic device 26. The circuitry 18 provides one or more of, modulation control to adjust at least one of output, frequency, phase and amplitude, random modulation of at least one, frequency, amplitude and phase for the modulation controller 20, external amplitude control to adjust output power synchronously with changes in RF frequency of the first DDS IC 16 when activating different profile pins of the first DDS IC 16, a programmable frequency spectrum, programmable amplitude spectrum and a programmable phase spectrum for the acousto-optic device 12 and external modulation controller 20 to adjust at least one of output, frequency, phase and amplitude.

The modulation controller 20 can produce only a low signal level output. This output is then put through final amplification 38 to bring it to the levels that the acousto-optic device 12 requires. The modulation controller 20 can be internal or external to the logic device 26.

A digital synthesizer 28 can be coupled to the modulation controller. The digital synthesizer, which can be the DDS IC 16 producing an RF output that is the RF input to the acousto-optic device. The user interface 22 is provided with inputs and outputs. By way of non-limiting example, one of the inputs provides for modulation of amplitude, frequency and/or phase. The inputs are smart recognition, sensors (temperature, light intensity, RF power and others), frequency profile select, trigger (triggers the playback mode), digital modulation, analog modulation (via high-speed parallel port to modulate frequency-amplitude-phase of the DDS IC), analog amplitude and or phase modulation external to the DDS IC (via the modulation controller or vector modulator), host computer communication, host modulation control communication, and service access communication via a device separate from the host computer.

The outputs are programmable frequency-amplitude-phase RF waveforms, RF waveform status, sensor status, device identification.

Control of frequency, phase and/or amplitude provides an amplitude response that can be a diffracted light intensity versus frequency which can be shaped to any geometric form. The amplitude response can have an arbitrary geometric form without normalization. With normalization the geometric form is flat and the deviation from flat is brought near to or at 0. In another embodiment, with normalization the geometric form is curved and the deviation from curved is brought near to or at 0.

In one embodiment, control of frequency, phase and/or amplitude provides an optical response that is a phase profile of an optical wavefront which can be shaped to any geometric form. The optical response can be an arbitrary geometric form without normalization, and with normalization the geometric form is flat and the deviation from flat is brought near to or at 0. In another embodiment, with normalization the geometric form is curved and the deviation from curved is brought near to or at 0.

A processor 30 is coupled to the user interface 22. The processor 30 includes logic resources that create the amplitude response described above. A sensor subsystem 32 is coupled to the processor 30. The sensor subsystem 32 is configured to receive a variety of different inputs including but not limited to, temperature, light intensity, RF power and the like. In one embodiment, the acousto-optic device 12 is associated with an amplifier.

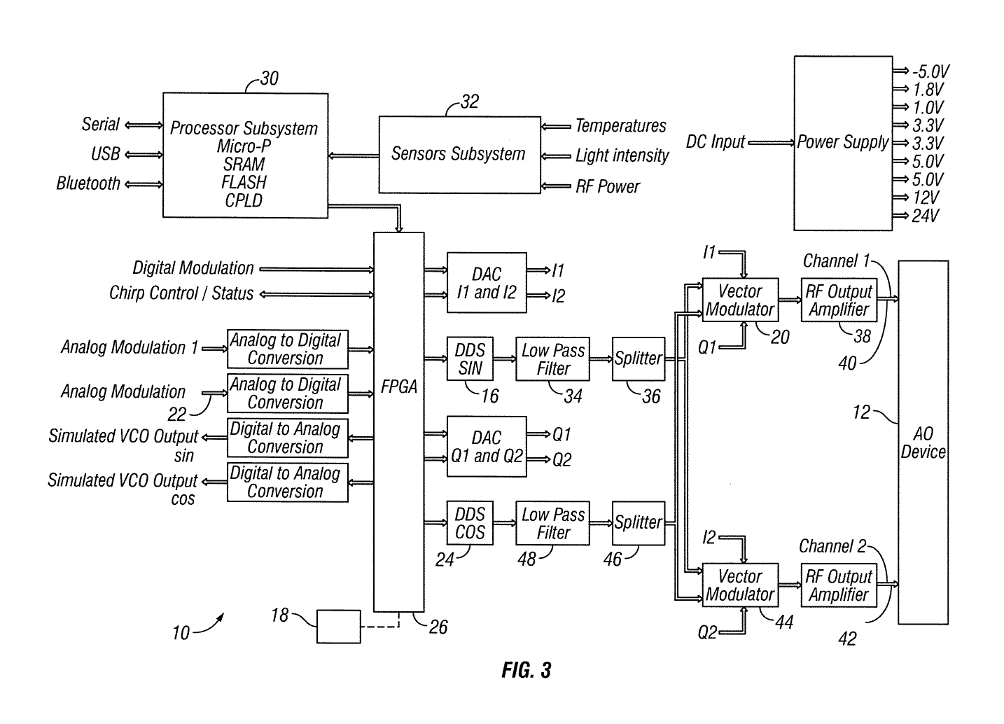

The system 10 can include a first low pass filter 34 coupled to the first DDS IC 16 and a first splitter 36, illustrated in FIG. 3, coupled to the first low pass filter 34. A modulation controller 20 can be coupled to the first low pass filter 34. An RF amplifier 38 is coupled to the modulation controller 20.

A plurality of modulation controllers 20 and DDS IC'S 16 can be provided. Each modulation controller 20 and DDS IC 16 provides an RF output to a different port.

It will be appreciated that N number of RF ports can be provided with N number of DDS IC's.

As illustrated in FIG. 3, first and second ports 40 and 42 are coupled to the first and second splitters 36 and 44. Phase differential is created between the first and second RF ports 40 and 42. First and second modulation controllers 20 and 44 are coupled to the first splitter 36 and to the second splitter 46. The first modulation controller 20 produces a first output at the first port 40, and the second modulation controller 44 produces a second output at the second port 42. The second DDS IC 24 is coupled to a second low pass filter 48 and to the second splitter 46.

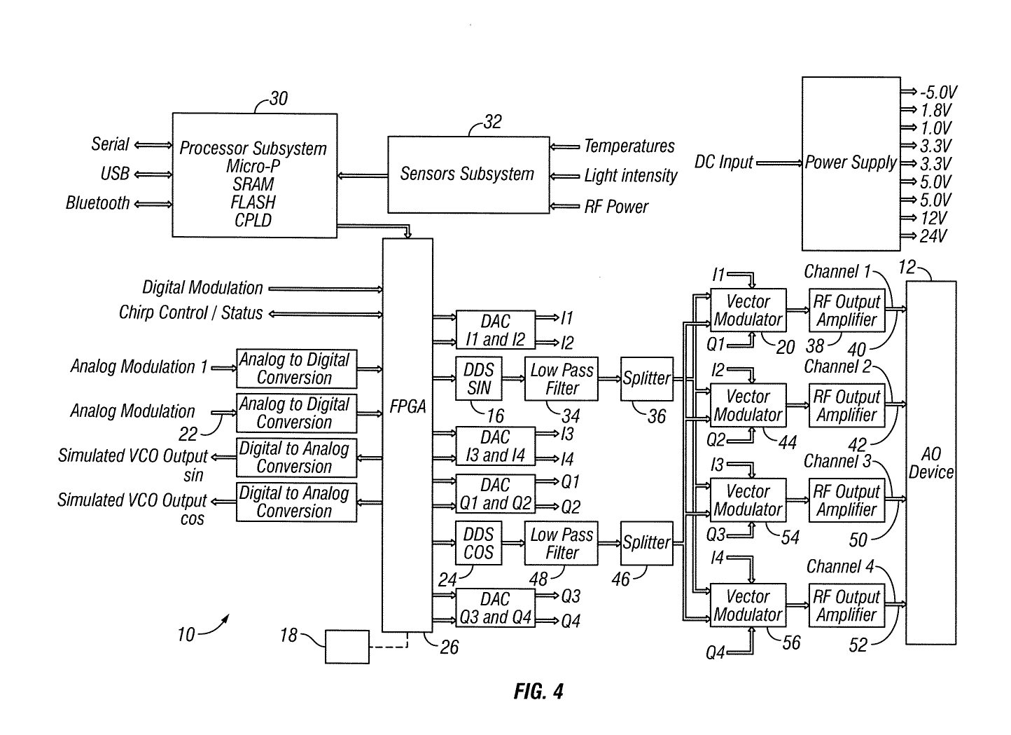

In another embodiment, illustrated in FIG. 4, the system 12 has four ports. When controlling phase, the first DDS IC 16 defines a sine path and the second DDS IC 24 defines a cosine path. The first and second splitters 36 and 48 produce I and Q paths that are coupled to modulation controllers. The modulation controllers 20 provide modulation of amplitude and/or phase. Phase differential is created between the first, second, third and fourth RF ports 40, 42, 50 and 52.

In one embodiment of the present invention, the circuitry 18 provides modulation control to adjust differential phase per port of the acousto-optic device 12 as a function of frequency. In another embodiment, the circuitry 18 provides external amplitude control synchronously with changes in frequency when activating a different profile for in-phase and quadrature channels.

The modulation controllers 20, 44 54 and 56 are coupled to the first splitter 36 and the second splitter 46, with I and Q paths.

The system 10 of the present invention can be utilized for a variety of different applications including but not limited to the following: semiconductor processing systems, optical scanning systems, inspection systems, imaging systems, communication systems, signal processing, holography, spectroscopy, microscopy, spectropolarimetry, biomedical testing instrument systems and the like.

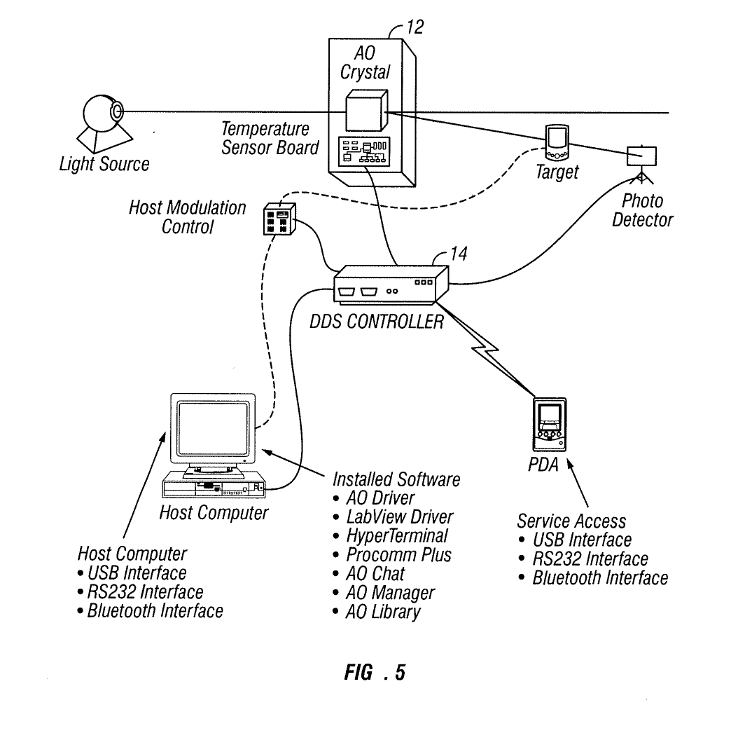

FIG. 5 illustrates one embodiment of the present invention with a light source coupled to the acousto-optic device, a target, photodetector, DDS controller 14, host modulation control, host computer and a PDA.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

1. An acousto-optic system, comprising:
an acousto-optic device;
a DDS controller coupled to the acousto-optic device, the DDS controller providing amplitude modulation to adjust output power synchronously with changes in frequency when activating a different frequency profile.

2. The system of claim 1, wherein the DDS controller includes at least a first DDS IC and a separate circuit that tracks a user's request to switch to a frequency profile and perform an amplitude adjustment external to the DDS IC.

3. The system of claim 1, wherein the DDS controller includes a first DDS IC and a second DDS IC.

4. The system of claim 2, wherein the speed to switch to the frequency profile and perform the amplitude adjustment external to the DDS IC is at least 1 millisecond.

5. The system of claim 2, wherein the speed to switch to the frequency profile and perform the amplitude adjustment external to the DDS IC is at least 1 microsecond.

6. The system of claim 2, wherein the speed to switch to the frequency profile and perform the amplitude adjustment external to the DDS IC is at least 500 nanoseconds.

7. The system of claim 2, wherein the speed to switch to the frequency profile and perform the amplitude adjustment external to the DDS IC is at least 100 nanoseconds.

8. The system of claim 2, wherein the speed to switch to the frequency profile and perform the amplitude adjustment external to the DDS IC is at least 10 nanoseconds.

9. The system of claim 2, wherein the speed to switch to the frequency profile and perform the amplitude adjustment external to the DDS IC is at least 4 nanoseconds.

10. The system of claim 2, wherein a change in the output RF frequency of the DDS IC is limited by a clock speed of the DDS IC.

11. The system of claim 2, wherein a change in the output RF amplitude of the DDS controller is limited by the bandwidth of ta modulation controller.

12. The system of claim 2, wherein a change in the output RF phase of the DDS controller is limited by the bandwidth of a modulation controller.

13. The system of claim 2, wherein frequencies are pre-loaded into frequency profile registers in the DDS IC and frequencies are injected into the acousto-optic device at optimized amplitudes.

14. The system of claim 2, wherein frequencies are randomly accessed and injected into the acousto-optic device at optimized amplitudes within 1 clock cycle of the DDS IC.

15. The system of claim 2, wherein frequencies are randomly accessed and injected into the acousto-optic device at optimized amplitudes within 2 clock cycles of the DDS IC.

16. The system of claim 2, wherein frequencies are randomly accessed and injected into the acousto-optic device at optimized amplitudes within 3 clock cycles of the DDS IC.

17. The system of claim 2, wherein frequencies are randomly accessed and injected into the acousto-optic device at optimized amplitudes within 4 clock cycles of the DDS IC.

18. The system of claim 2, wherein frequencies are randomly accessed and injected into the acousto-optic device at optimized amplitudes within 5 clock cycles of the DDS IC.

19. The system of claim 2, wherein frequencies are sequentially accessed and injected into the acousto-optic device at optimized amplitudes at a switching speed of at least 1 megahertz.

20. The system of claim 2, wherein frequencies are sequentially accessed and injected into the acousto-optic device at optimized amplitudes at a switching speed of at least 2 megahertz.

21. The system of claim 2, wherein frequencies are sequentially accessed and injected into the acousto-optic device at optimized amplitudes at a switching speed of at least 5 megahertz.

22. The system of claim 2, wherein frequencies are sequentially accessed and injected into the acousto-optic device at optimized amplitudes at a switching speed of at least 50 megahertz.

23. The system of claim 2, wherein frequencies are sequentially accessed and injected into the acousto-optic device at optimized amplitudes at a switching speed of at least 100 megahertz.

24. The system of claim 2, wherein frequencies are sequentially accessed and injected into the acousto-optic device at optimized amplitudes at a switching speed of at least 200 megahertz.

25. The system of claim 2, wherein frequencies are sequentially accessed and injected into the acousto-optic device at optimized amplitudes at a switching speed of at least 250 megahertz.

26. The system of claim 1, wherein the DDS IC operates in a direct switch mode and randomly selects frequencies from the DDS IC and then injects frequencies.

27. The system of claim 1, wherein the DDS IC operates in a RAM mode with pre-load frequencies in the DDS IC, and with the DDS IC in playback mode generating a waveform at least at the clock rate of the DDS IC.

28. An acousto-optic system, comprising:
an acousto-optic device;
a DDS controller coupled to the acousto-optic device; and
wherein the DDS controller includes at least a first DDS IC and a separate circuit that tracks a user's request to directly frequency modulate the DDS IC.

29. The system of claim 28, wherein a modulation controller in the DDS controller is externally modulated by a host interface.

30. The system of claim 28, further comprising:
a second DDS IC chip;
a modulation controller; and
a host interface that sends modulation data to the modulation controller and modulates amplitude and phase external to the first and second DDS ICs.

31. An acousto-optic system, comprising:
an acousto-optic device;
a DDS controller coupled to the acousto-optic device
wherein the DDS controller includes at least a first DDS IC and a separate circuit to directly modulate amplitude or frequency of the DDS IC.

32. The system of claim 31, wherein the first DDS IC and the separate circuit directly simultaneously modulates amplitude and frequency of the DDS IC.

33. The system of claim 31, further comprising:
a second DDS IC chip;
a modulation controller; and
a host interface that sends modulation data to the modulation controller and frequency modulate the first and second DDS ICs and externally phase modulates the first and second DDS ICs.

34. The system of claim 33, wherein the first DDS IC and the separate circuit simultaneously modulates frequency and phase of the DDS controller.

35. An acousto-optic system, comprising:
an acousto-optic device configured to receive an RF input;
at least a first DDS IC;
a logic device coupled to the first DDS IC; and
circuitry coupled to or incorporated into the logic device, the circuitry providing at least one of, modulation control to adjust at least one of output, frequency, phase and amplitude, random modulation of at least one, frequency, amplitude and phase for a DDS controller, external amplitude control to adjust output power synchronously with changes in RF frequency of the first DDS IC when activating different profile pins of the first DDS IC, a programmable frequency spectrum, programmable amplitude spectrum and a programmable phase spectrum for the acousto-optic device and external modulation control to adjust at least one of output, frequency, phase and amplitude.

36. The system of claim 35, wherein the logic device includes a modulation controller.

37. The system of claim 35, further comprising:
a modulation controller external to the logic device.

38. The system of claim 36, further comprising:
a digital synthesizer coupled to the modulation controller, the digital synthesizer producing an RF output that is the RF input to the acousto-optic device.

39. The system of claim 35, further comprising:
a user interface with inputs and outputs, at least one of an input providing modulation for at least one of, amplitude, frequency and phase.

40. The system of claim 35, wherein control of at least one of frequency, phase and amplitude provides an amplitude response that is a diffracted light intensity versus frequency which can be shaped to any geometric form.

41. The system of claim 40, wherein the response is of arbitrary geometric form without normalization, and with normalization the geometric form is flat and the deviation from flat is brought near to or at 0.

42. The system of claim 40, wherein the response is of arbitrary geometric form without normalization, and with normalization the geometric form is curved and the deviation from curved is brought near to or at 0.

43. The system of claim 35, wherein control of at least one of frequency, phase and amplitude provides an optical response that is a phase profile of an optical wavefront which can be shaped to any geometric form.

44. The system of claim 43, wherein the response is of arbitrary geometric form without normalization, and with normalization the geometric form is flat and the deviation from flat is brought near to or at 0.

45. The system of claim 43, wherein the response is of arbitrary geometric form without normalization, and with normalization the geometric form is curved and the deviation from curved is brought near to or at 0.

46. The system of claim 35, further comprising:
a first low pass filter coupled to the first DDS IC; and
a RF amplifier coupled to the first low pass filter.

47. The system of claim 35, wherein a second DDS IC is provided.

48. The system of claim 35, wherein a plurality of DDS IC's are provided.

49. The system of claim 48, wherein a plurality of modulation controllers are provided, each of a modulation controller providing an RF output to a different port.

50. The system of claim 49, wherein each of a modulation controller is part of the logic device or is external to the logic device.

51. The system of claim 47, wherein the DDS controller is a two-port RF output.

52. The system of claim 47, further comprising:
first and second modulation controllers coupled to first and second splitters, the first modulation controller producing a first output at the first RF port and the second modulation controller producing a second output at the second RF port.

53. The system of claim 51, wherein phase differential is created between the first and second RF ports.

54. The system of claim 47, wherein the DDS controller is a four-port RF output.

55. The system of claim 54, further comprising:
first, second, third and fourth modulation controllers coupled to the first splitter and second splitter, the first modulation controller producing a first output at the first RF port and the second modulation controller producing a second output at the second RF port and the third modulation controller producing a third output at the third RF port and the fourth modulation controller producing a fourth output at the fourth RF port.

56. The system of claim 55, wherein the first, second, third and fourth modulation controllers are part of the logic device or are external to the logic device.

57. The system of claim 54, wherein phase differential is created between the first, second, third, and fourth RF ports.

58. The system of claim 47, wherein the circuitry provides modulation control to adjust differential phase per port of the acousto-optic device as a function of frequency.

51. The system of claim 50, wherein the circuitry provides external amplitude control synchronously with changes in frequency when activating a different profile for in-phase and quadrature channels.

52. The system of claim 35, wherein a plurality of modulation controllers are provided, each of a modulation controller providing an RF output to a different port.

53. The system of claim 35, wherein the logic device is selected from at least one of, a CPLD, PLD, and ASIC and FPGA 54. The system of claim 35, further comprising:
a processor coupled to a user interface.

55. The system of claim 54, wherein the processor includes logic resources that creates an amplitude response, the amplitude response being a diffracted light intensity versus frequency shapeable to any geometric form, the amplitude response being a feedback to the acousto-optic device.

56. The system of claim 55, wherein the response created by the processor is of arbitrary geometric form without normalization, and with normalization the geometric form is flat and the deviation from flat is brought near to or at 0.

57. The system of claim 55, wherein the response created by the processor is of arbitrary geometric form without normalization, and with normalization the geometric form is curved and the deviation from curved is brought near to or at 0.

56. The system of claim 54, wherein the processor includes logic resources that creates an optical response, the optical response being a phase profile of an optical wavefront shapeable to any geometric form, the optical response providing a feedback to the acousto-optic device.

56. The system of claim 56, wherein the response created by the processor is of arbitrary geometric form without normalization, and with normalization the geometric form is flat and the deviation from flat is brought near to or at 0.

57. The system of claim 56, wherein the response created by the processor is of arbitrary geometric form without normalization, and with normalization the geometric form is curved and the deviation from curved is brought near to or at 0.

58. The system of claim 54, further comprising:
a sensor subsystem coupled to the processor, the sensor subsystem configured to receive inputs selected from at least one of, temperature, light intensity and RF power.

59. The system of claim 35, further comprising:
smart recognition that embeds device identification for passing behavioral data to the DDS controller.

60. The system of claim 35, further comprising:
a plurality of modulation controllers, each of a modulation controller providing an RF output to a different channel and each of a modulation controller is part of the logic device or is external to the logic device.

61. The system of claim 35, wherein the acousto-optic device associated with an amplifier.

62. The system of claim 35, wherein the acousto-optic device is an enhanced Bragg bandwidth beam steered device, and the circuitry provides at least one of, programmable frequency, amplitude and phase for the acousto-optic beam steered device.

63. The system of claim 35, wherein the acousto-optic device is an acousto-optic tunable filter, and the circuitry provides at least one of, programmable frequency, amplitude and phase for the acousto-optic tunable filter device.
